(19) United States
(12) Patent Application Publication
(10) Pub. No.: US 2019/0141867 A1
(43) Pub. Date: May 9, 2019

(54) SHIELDING FILM AND METHOD OF MANUFACTURING THE SAME

(71) Applicant: APAQ TECHNOLOGY CO., LTD., Miaoli County (TW)

(72) Inventors: MING-GOO CHIEN, TAICHUNG CITY (TW); CHIA-YU WU, NEW TAIPEI CITY (TW)

(21) Appl. No.: 15/893,768

(22) Filed: Feb. 12, 2018

(30) Foreign Application Priority Data
Nov. 3, 2017 (TW) 106138114

(51) Int. Cl. H05K 9/00; B32B 15/01; B32B 15/20

(52) U.S. Cl. CPC H05K 9/0088; B32B 15/017; B32B 2255/205; B32B 2457/00; B32B 2255/06; B32B 15/20

(57) ABSTRACT

The present invention provides a shielding film and a method of manufacturing the same. The shielding film includes a base structure, a medium structure formed on the base structure, and a shielding structure formed on the medium structure. The shielding structure is a high density structure without voids or with few voids, so that at least one of an electric conductivity, a thermal conductivity, an EMI shielding performance and a flexibility of the shielding film is increased.

### FIELD OF THE INVENTION

The present disclosure relates to a shielding film and a method of manufacturing the same, and more particularly to a shielding film having a high density structure without voids or with few voids, and a method of manufacturing the same.

### BACKGROUND OF THE INVENTION

Recently, with the improvement of technologies concerning battery electrodes, high conductivity films, and cooling components in electronics, the costs associated with graphene and carbon nanotubes have been reduced. Therefore, innovative applications of graphene and carbon nanotubes materials have been developed. In the prior art, well-known applications of graphene and carbon nanotubes include functional fabrics, sports equipment, electromagnetic shielding materials and biomedical applications. Currently, a number of electromagnetic shielding materials have been commercialized and made available on the market.

Existing shielding materials are complex of thin films or braided metal (copper, aluminum or iron) or alloys thereof and compounds of magnetic materials such as ferrite materials (i.e., iron, manganese, zinc or nickel).

### SUMMARY OF THE INVENTION

One aspect of the present disclosure relates to a shielding film and a method of manufacturing the same.

One of the embodiments of the present disclosure provides a shielding film, including a base structure, a medium structure formed on the base structure, and a shielding structure formed on the medium structure. The shielding structure is a high density structure without voids or with few voids, so that at least one of an electric conductivity, a thermal conductivity, an EMI shielding performance and a flexibility of the shielding film is increased.

More particularly, the medium structure is formed on the base structure by vacuum sputtering, evaporation, physical vapor deposition or chemical vapor deposition, and the shielding structure is formed on the medium structure by vacuum sputtering, evaporation, physical vapor deposition or chemical vapor deposition. The base structure is an Al base, a Cu base or a composite base having an Al layer and a PET layer, the medium structure is a Ti material layer, a Cr material layer, a Ta material layer, a TiN composite material layer, a TaN composite material layer or a CrN composite material layer having a thickness of about 10 to 200 nm, and the shielding structure is an amorphous carbon layer having a thickness of about 10 to 500 nm.

More particularly, the medium structure is a single medium layer or a plurality of medium layers stacked on top of one another, and the shielding structure is a single shielding layer or a plurality of shielding layers stacked on top of one another. The single medium layer or each of the plurality of medium layers has a thickness of about 10 to 200 nm and is a Ti material layer, a Cr material layer, a Ta material layer, a TiN composite material layer, a TaN composite material layer or a CrN composite material layer, and the single shielding layer or each of the plurality of shielding layers is an amorphous carbon layer having a thickness of about 10 to 500 nm.

More particularly, the shielding film further includes a first intermetallic compound layer connected between the base structure and the medium structure by a heat treatment, and a second intermetallic compound layer connected between the medium structure and the shielding structure by a heat treatment. The medium structure is a single medium layer or a plurality of medium layers stacked on top of one another, and the shielding structure is a single shielding layer or a plurality of shielding layers stacked on top of one another. The single medium layer or each of the plurality of medium layers has a thickness of about 10 to 200 nm and is a Ti material layer, a Cr material layer, a Ta material layer, a TiN composite material layer, a TaN composite material layer or a CrN composite material layer, and the single shielding layer or each of the plurality of shielding layers is an amorphous carbon layer having a thickness of about 10 to 500 nm.

Another one of the embodiments of the present disclosure provides a method of manufacturing a shielding film, including: providing a base structure; transmitting the base structure by a roll-to-roll device; adjusting the tension of the base structure by a tension controller that is electrically connected to the roll-to-roll device; forming a medium structure on the base structure; and forming a shielding structure on the medium structure. The shielding structure is a high density structure without voids or with few voids, so that one of an electric conductivity, a thermal conductivity, an EMI shielding performance and a flexibility of the shielding film is increased.

More particularly, after the step of forming the shielding structure on the medium structure, the method further includes forming a first intermetallic compound layer connected between the base structure and the medium structure by a heat treatment, and a second intermetallic compound layer connected between the medium structure and the shielding structure by a heat treatment. The medium structure is a single medium layer or a plurality of medium layers stacked on top of one another, and the shielding structure is a single shielding layer or a plurality of shielding layers stacked on top of one another. The single medium layer or each of the plurality of medium layers has a thickness of about 10 to 200 nm and is a Ti material layer, a Cr material layer, a Ta material layer, a TiN composite material layer, a TaN composite material layer or a CrN composite material layer, and the single shielding layer or each of the plurality of shielding layers is an amorphous carbon layer having a thickness of about 10 to 500 nm.

Yet another one of the embodiments of the present disclosure provides a shielding film, including a base structure, a medium structure formed on the base structure, and a shielding structure formed on the medium structure. As the entire shielding structure is of a non-volatile substance, the porosity of the shielding structure can be zero or close to zero.

More particularly, the medium structure is formed on the base structure by vacuum sputtering, evaporation, physical vapor deposition or chemical vapor deposition, and the shielding structure is formed on the medium structure by vacuum sputtering, evaporation, physical vapor deposition or chemical vapor deposition. The base structure is an Al base, a Cu base or a composite base having an Al layer and a PET layer, the medium structure with a thickness of about 10 to 200 nm is a Ti material layer, a Cr material layer, a Ta material layer, a TiN composite material layer, a TaN composite material layer or a CrN composite material layer, and the shielding structure is an amorphous carbon layer having a thickness of about 10 to 500 nm. The shielding structure is a high density structure without voids or with few voids, so that at least one of an electric conductivity, a thermal conductivity, an EMI shielding performance and a flexibility of the shielding film is increased.

More particularly, the medium structure is a single medium layer or a plurality of medium layers stacked on top of one another, and the shielding structure is a single shielding layer or a plurality of shielding layers stacked on top of one another. The single medium layer or each of the plurality of medium layers has a thickness of about 10 to 200 nm and is a Ti material layer, a Cr material layer, a Ta material layer, a TiN composite material layer, a TaN composite material layer or a CrN composite material layer, and the single shielding layer or each of the plurality of shielding layers is an amorphous carbon layer having a thickness of about 10 to 500 nm. The shielding structure is a high density structure without voids or with few voids, so that at least one of an electric conductivity, a thermal conductivity, an EMI shielding performance and a flexibility of the shielding film is increased.

More particularly, the shielding film further includes a first intermetallic compound layer connected between the base structure and the medium structure by a heat treatment, and a second intermetallic compound layer connected between the medium structure and the shielding structure by a heat treatment. The medium structure is a single medium layer or a plurality of medium layers stacked on top of one another, and the shielding structure is a single shielding layer or a plurality of shielding layers stacked on top of one another. The single medium layer or each of the plurality of medium layers has a thickness of about 10 to 200 nm and is a Ti material layer, a Cr material layer, a Ta material layer, a TiN composite material layer, a TaN composite material layer or a CrN composite material layer, and the single shielding layer or each of the plurality of shielding layers is an amorphous carbon layer having a thickness of about 10 to 500 nm. The shielding structure is a high density structure without voids or with few voids, so that at least one of an electric conductivity, a thermal conductivity, an EMI shielding performance and a flexibility of the shielding film is increased.

Therefore, the shielding structure 3 is a high density structure without voids or with few voids, or the porosity of the shielding structure 3 made of non-volatile substance is zero or close to zero, so that at least one of the electric conductivity, the thermal conductivity, the EMI shielding performance and the flexibility of the shielding film F is increased in virtue of the shielding structure 3 without voids (i.e., the porosity is zero) or with few voids (i.e., the porosity is close to zero).

To further understand the techniques, means and effects of the present disclosure, the following detailed descriptions and appended drawings are hereby referred to, such that, and through which, the purposes, features and aspects of the present disclosure can be thoroughly and concretely appreciated. However, the appended drawings are provided solely for reference and illustration, without any intention to limit the present disclosure.

### BRIEF DESCRIPTION OF THE DRAWINGS

The accompanying drawings are included to provide a further understanding of the present disclosure, and are incorporated in and constitute a part of this specification. The drawings illustrate exemplary embodiments of the present disclosure and, together with the description, serve to explain the principles of the present disclosure.

FIG. 1 shows a flowchart of a method of manufacturing a shielding film according to a first embodiment of the present disclosure;

FIG. 2 shows a schematic view of step S100 of the method of manufacturing the shielding film according to the first embodiment of the present disclosure;

FIG. 3 shows a schematic view of step S102 and step S104 of the method of manufacturing the shielding film according to the first embodiment of the present disclosure;

FIG. 4 shows a schematic view of step S106 of the method of manufacturing the shielding film according to the first embodiment of the present disclosure;

FIG. 5 shows a schematic view of step S108 of the method of manufacturing the shielding film according to the first embodiment of the present disclosure;

FIG. 6 shows a schematic view of the shielding film using a plurality of medium layers stacked on top of one another according to the first embodiment of the present disclosure;

FIG. 7 shows a schematic view of the shielding film using a plurality of shielding layers stacked on top of one another according to the first embodiment of the present disclosure;

FIG. 8 shows a flowchart of a method of manufacturing a shielding film according to a second embodiment of the present disclosure; and

FIG. 9 shows a schematic view of the shielding film according to the second embodiment of the present disclosure.

### DETAILED DESCRIPTION OF THE PREFERRED EMBODIMENTS

Embodiments of a shielding film and a method of manufacturing the same according to the present disclosure are described herein. Other advantages and objectives of the present disclosure can be easily understood by one skilled in the art from the disclosure. The present disclosure can be applied in different embodiments. Various modifications and variations can be made to various details in the description for different applications without departing from the scope of the present disclosure. The drawings of the present disclosure are provided only for simple illustrations, but are not drawn to scale and do not reflect the actual relative dimensions. The following embodiments are provided to describe in detail the concept of the present disclosure, and are not intended to limit the scope thereof in any way.

It should be noted that the terms “first”, “second”, “third”, etc. may be used herein to describe various elements or signals; however, such terms should not be construed as limiting the elements or signals. These terms are used mainly for distinguishing one element from another, or distinguishing one signal from another. In addition, the term “or” may be used to include any one or any combination of the listed items, as the case may be.

### First Embodiment

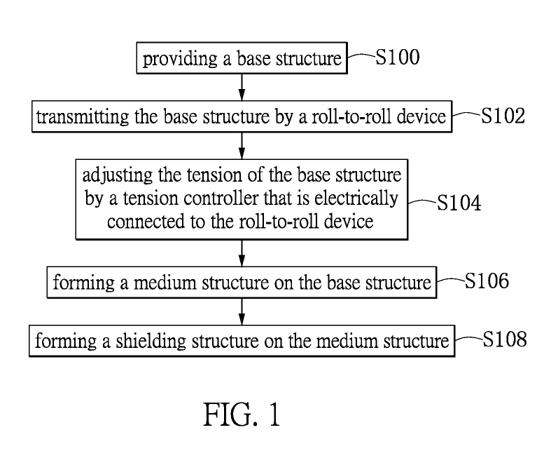

Referring to FIG. 1 to FIG. 5, the first embodiment of the present disclosure provides a method of manufacturing a shielding film, including the following steps:

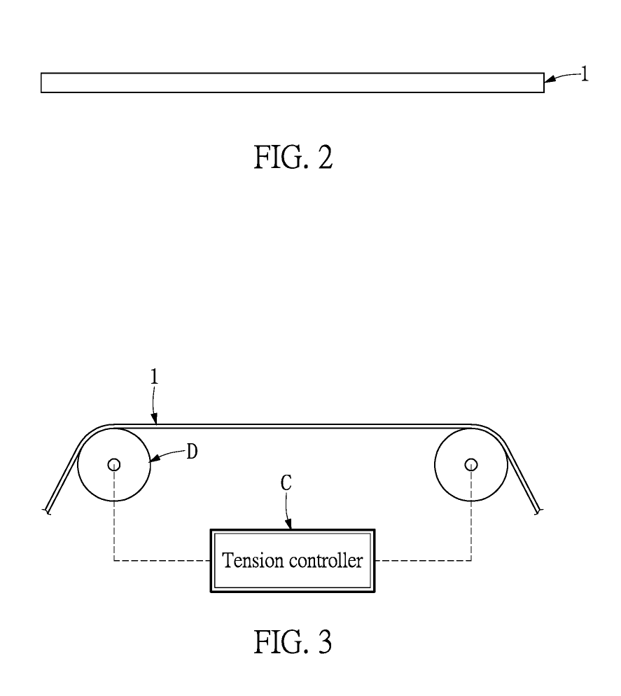

Firstly, referring to FIG. 1 and FIG. 2, step S100 includes providing a base structure 1. For example, the base structure may be an Al base, a Cu base or a composite base having an Al layer and a PET layer, but the example is not meant to limit the scope of the present disclosure.

Next, referring to FIG. 1 to FIG. 3, step S102 includes transmitting the base structure 1 by a roll-to-roll device D, and step S104 includes adjusting the tension of the base structure 1 by a tension controller C that is electrically connected to the roll-to-roll device D. For example, a distance between two rollers of the roll-to-roll device D can be changed by the tension controller C so as to adjust the tension of the base structure 1.

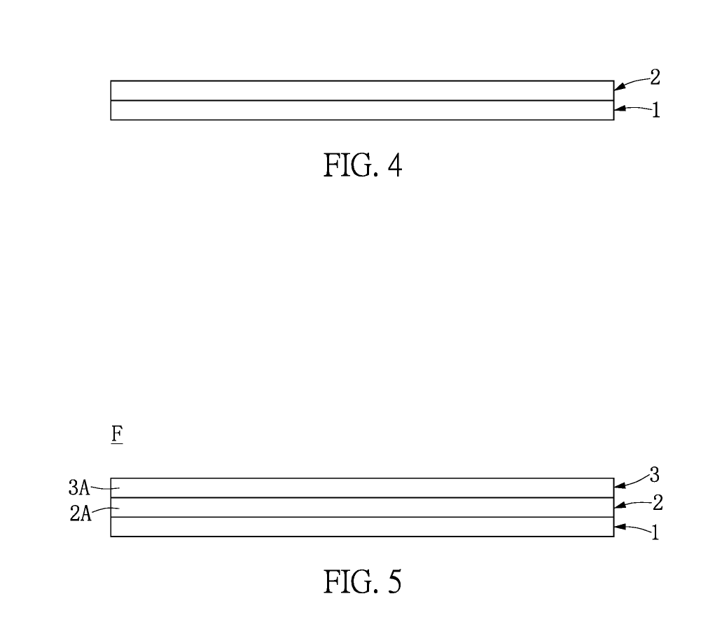

Afterward, referring to FIG. 1 and FIG. 4, step S106 includes forming a medium structure 2 on the base structure 1. For example, the medium structure 2 can be formed on the base structure 1 by vacuum sputtering, evaporation, physical vapor deposition (PVD), chemical vapor deposition (CVD), or any vacuum forming, so that the medium structure 2 can be a high density structure without voids or with few voids. In addition, the medium structure 2 with a thickness of about 10 to 200 nm may be a Ti material layer, a Cr material layer, a Ta material layer, a TiN composite material layer, a TaN composite material layer or a CrN composite material layer, but the example is not meant to limit the scope of the present disclosure.

Then, referring to FIG. 1 and FIG. 5, step S108 includes forming a shielding structure 3 on the medium structure 2, and the shielding structure 3 may be a high density structure without voids or with few voids. That is to say, after coating a shielding paste with a non-volatile substance on the medium structure 2, the shielding paste can be solidified to form the shielding structure 3 as a high density structure without voids or with few voids. Hence, the entire shielding structure 3 is of a non-volatile substance, and the porosity of the shielding structure 3 can be zero or close to zero. More particularly, the shielding structure 3 may be a high density structure without voids or with few voids, so that at least one of an electric conductivity, a thermal conductivity, an EMI shielding performance and a flexibility of the shielding film F can be increased in virtue of the shielding structure 3. For example, the shielding structure 3 can be formed on the medium structure 2 by vacuum sputtering, evaporation, physical vapor deposition (PVD), chemical vapor deposition (CVD), or any vacuum forming, so that the shielding structure 3 can be a high density structure without voids or with few voids. In addition, the shielding structure 3 may be an amorphous carbon layer having a thickness of about 10 to 500 nm, and the amorphous carbon layer can be composed of sp2 bonded carbon and sp3 bonded carbon.

Therefore, the shielding film F can be completed by the steps of S100 to S108, so that the first embodiment of the present invention further provides a shielding film F, including a base structure 1, a medium structure 2 formed on the base structure 1, and a shielding structure 3 formed on the medium structure 2 as shown in FIG. 5. It should be noted that the shielding structure 3 may be a high density structure without voids or with few voids. For example, the whole shielding structure 3 may be a non-volatile substance, so that the porosity of the shielding structure 3 is zero or close to zero. Furthermore, at least one of an electric conductivity, a thermal conductivity, an EMI shielding performance and a flexibility of the shielding film F can be increased in virtue of the shielding structure 3. That is to say, the shielding structure 3 may be a high density structure without voids or with few voids, or the porosity of the shielding structure 3 is zero or close to zero, so that at least one of the electric conductivity, the thermal conductivity, the EMI shielding performance and the flexibility of the shielding film F can be increased in virtue of the shielding structure 3 without voids (i.e., the porosity is zero) or with few voids (i.e., the porosity is close to zero).

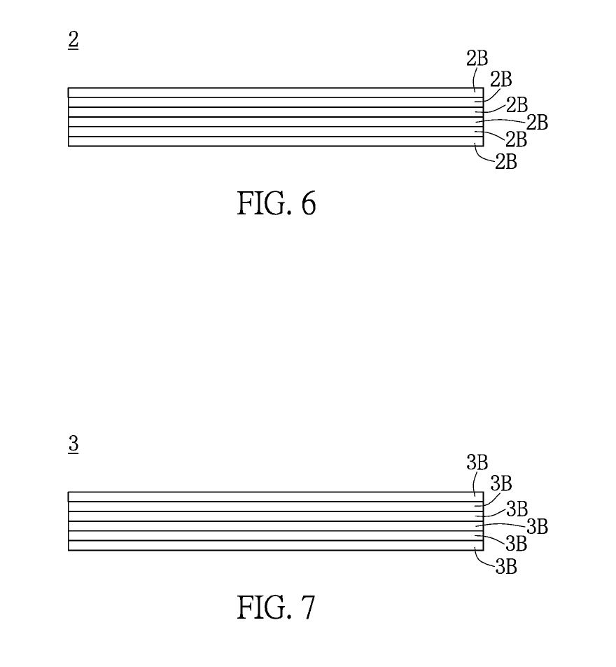

It should be noted that the medium structure 2 may be a single medium layer 2A (as shown in FIG. 4) or a plurality of medium layers 2B stacked on top of one another (as shown in FIG. 6) according to different requirements as shown in FIG. 4 or FIG. 6. In addition, the shielding structure 3 may be a single shielding layer 3A (as shown in FIG. 4) or a plurality of shielding layers 3B stacked on top of one another (as shown in FIG. 7) according to different requirements as shown in FIG. 4 or FIG. 7. For example, the single medium layer 2A or each of the plurality of medium layers 2B can have a thickness of about 10 to 200 nm, and the single medium layer 2A or each of the plurality of medium layers 2B may be a Ti material layer, a Cr material layer, a Ta material layer, a TiN composite material layer, a TaN composite material layer or a CrN composite material layer. In addition, the single shielding layer 3A or each of the plurality of shielding layers 3B may be an amorphous carbon layer having a thickness of about 10 to 500 nm. However, the example is not meant to limit the scope of the present disclosure.

### Second Embodiment

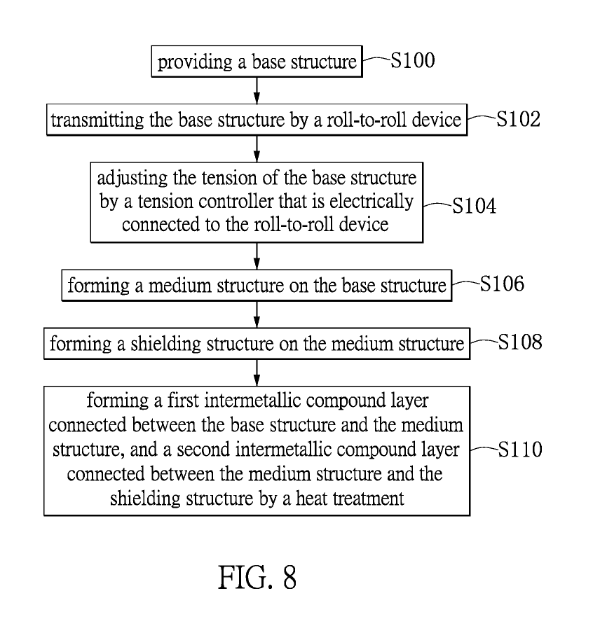

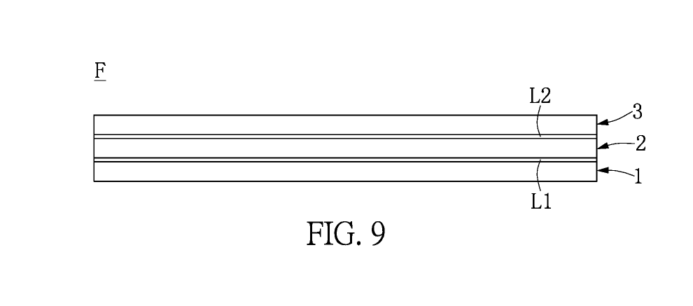

Referring to FIG. 8 and FIG. 9, the second embodiment of the present disclosure provides a shielding film and a method of manufacturing the same. Comparing FIG. 8 with FIG. 1, and comparing FIG. 9 with FIG. 5, the difference between the second embodiment and the first embodiment is as follows: in the second embodiment, after the step S108 of forming the shielding structure 3 on the medium structure 2, the method further includes forming, by a heat treatment such as annealing, a first intermetallic compound layer L1 connected between the base structure 1 and the medium structure 2, and a second intermetallic compound layer L2 connected between the medium structure 2 and the shielding structure 3 (S110). That is to say, the shielding film F of the second embodiment further includes a first intermetallic compound layer L1 connected between the base structure 1 and the medium structure 2 by the heat treatment, and a second intermetallic compound layer L2 connected between the medium structure 2 and the shielding structure 3 by the heat treatment. For example, both or one of the base structure 1 and the medium structure 2 can be heat-treated to form the first intermetallic compound layer L1, and both or one of the medium structure 2 and the shielding structure 3 can be heat-treated to form the second intermetallic compound layer L2.

It should be noted that the medium structure 2 may be a single medium layer or a plurality of medium layers stacked on top of one another according to different requirements. In addition, the shielding structure 3 may be a single shielding layer or a plurality of shielding layers stacked on top of one another according to different requirements. For example, the single medium layer or each of the plurality of medium layers has a thickness of about 10 to 200 nm, and the single medium layer or each of the plurality of medium layers is a Ti material layer, a Cr material layer, a Ta material layer, a TiN composite material layer, a TaN composite material layer or a CrN composite material layer, and the single shielding layer or each of the plurality of shielding layers is an amorphous carbon layer having a thickness of about 10 to 500 nm. However, the example is not meant to limit the scope of the present disclosure.

It should be noted that the shielding structure 3 may be a high density structure without voids or with few voids. That is to say, the entire shielding structure 3 is of a non-volatile substance, so that the porosity of the shielding structure 3 is zero or close to zero. In addition, one of an electric conductivity, a thermal conductivity, an EMI shielding performance and a flexibility of the shielding film F can be increased in virtue of the shielding structure 3. That is to say, the shielding structure 3 may be a high density structure without voids or with few voids, or the porosity of the shielding structure 3 is zero or close to zero, so that at least one of the electric conductivity, the thermal conductivity, the EMI shielding performance and the flexibility of the shielding film F can be increased in virtue of the shielding structure 3 without voids (i.e., the porosity is zero) or with few voids (i.e., the porosity is close to zero).

In conclusion, at least one of an electric conductivity, a thermal conductivity, an EMI shielding performance and a flexibility of the shielding film can be increased due to “the shielding structure 3 being a high density structure without voids or with few voids” or “the porosity of the shielding structure 3 that is made of non-volatile substance being zero or close to zero”. That is to say, the shielding structure 3 is a high density structure without voids or with few voids, or the porosity of the shielding structure 3 made of non-volatile substance is zero or close to zero, so that at least one of the electric conductivity, the thermal conductivity, the EMI shielding performance and the flexibility of the shielding film F is increased in virtue of the shielding structure 3 without voids (i.e., the porosity is zero) or with few voids (i.e., the porosity is close to zero).

More particularly, the shielding film F and the method of manufacturing the same of the present disclosure can provide the following advantages:

(1) The shielding structure 3 can provide better EMI shielding effect due to high density or low porosity of the shielding structure 3. That is to say, the EMI shielding performance of the shielding film F can be effectively increased in virtue of the shielding structure 3.

(2) The shielding structure 3 can provide better conductive efficiency due to high density or low porosity of the shielding structure 3. That is to say, the electric conductivity of the shielding film F can be effectively increased in virtue of the shielding structure 3.

(3) The shielding structure 3 can provide better heat dissipating efficiency due to high density or low porosity of the shielding structure 3. That is to say, the thermal conductivity of the shielding film F can be effectively increased in virtue of the shielding structure 3.

(4) The shielding structure 3 can provide better bending capabilities due to high density or low porosity of the shielding structure 3. That is to say, the flexibility of the shielding film F can be effectively increased in virtue of the shielding structure 3.

(5) The shielding structure 3 can provide better EMI shielding effect, better conductive efficiency, better heat dissipating efficiency, and better bending capabilities due to high density or low porosity of the shielding structure 3, even if the shielding structure 3 only has a thickness of about 10 to 500 nm. Hence, the material cost of the shielding film F can be reduced due to the thin thickness of the shielding structure 3.

(6) The roll-to-roll device D with the tension controller C can be used for mass production of the shielding film F.

The aforementioned descriptions merely represent the preferred embodiments of the present disclosure, without any intention to limit the scope of the present disclosure which is fully described only within the following claims. Various equivalent changes, alterations or modifications based on the claims of the present disclosure are all, consequently, viewed as being embraced by the scope of the present disclosure.

What is claimed is:

1. A shielding film, comprising:
a base structure;
a medium structure formed on the base structure; and
a shielding structure formed on the medium structure;
wherein the shielding structure is a high density structure without voids or with few voids, so that at least one of an electric conductivity, a thermal conductivity, an EMI shielding performance and a flexibility of the shielding film is increased.

2. The shielding film of claim 1, wherein the medium structure is formed on the base structure by vacuum sputtering, evaporation, physical vapor deposition or chemical vapor deposition, and the shielding structure is formed on the medium structure by vacuum sputtering, evaporation, physical vapor deposition or chemical vapor deposition, and wherein the base structure is an Al base, a Cu base or a composite base having an Al layer and a PET layer, the medium structure is a Ti material layer, a Cr material layer, a Ta material layer, a TiN composite material layer, a TaN composite material layer or a CrN composite material layer having a thickness of about 10 to 200 nm, and the shielding structure is an amorphous carbon layer having a thickness of about 10 to 500 nm.

3. The shielding film of claim 1, wherein the medium structure is a single medium layer or a plurality of medium layers stacked on top of one another, and the shielding structure is a single shielding layer or a plurality of shielding layers stacked on top of one another, and wherein the single medium layer or each of the plurality of medium layers has a thickness of about 10 to 200 nm and is a Ti material layer, a Cr material layer, a Ta material layer, a TiN composite material layer, a TaN composite material layer or a CrN composite material layer, and the single shielding layer or each of the plurality of shielding layers is an amorphous carbon layer having a thickness of about 10 to 500 nm.

4. The shielding film of claim 1, further comprising a first intermetallic compound layer connected between the base structure and the medium structure by heat treatment, and a second intermetallic compound layer connected between the medium structure and the shielding structure by heat treatment, wherein the medium structure is a single medium layer or a plurality of medium layers stacked on top of one another, and the shielding structure is a single shielding layer or a plurality of shielding layers stacked on top of one another, and wherein the single medium layer or each of the plurality of medium layers has a thickness of about 10 to 200 nm and is a Ti material layer, a Cr material layer, a Ta material layer, a TiN composite material layer, a TaN composite material layer or a CrN composite material layer, and the single shielding layer or each of the plurality of shielding layers is an amorphous carbon layer having a thickness of about 10 to 500 nm.

5. A method of manufacturing a shielding film, comprising:
providing a base structure;
transmitting the base structure by a roll-to-roll device;
adjusting the tension of the base structure by a tension controller that is electrically connected to the roll-to-roll device;
forming a medium structure on the base structure; and
forming a shielding structure on the medium structure;
wherein the shielding structure is a high density structure without voids or with few voids, so that at least one of an electric conductivity, a thermal conductivity, an EMI shielding performance and a flexibility of the shielding film is increased.

6. The method of claim 5, wherein after the step of forming the shielding structure on the medium structure, the method further comprises: forming a first intermetallic compound layer connected between the base structure and the medium structure by heat treatment, and a second intermetallic compound layer connected between the medium structure and the shielding structure by heat treatment, wherein the medium structure is a single medium layer or a plurality of medium layers stacked on top of one another, and the shielding structure is a single shielding layer or a plurality of shielding layers stacked on top of one another, and wherein the single medium layer or each of the plurality of medium layers has a thickness of about 10 to 200 nm and is a Ti material layer, a Cr material layer, a Ta material layer, a TiN composite material layer, a TaN composite material layer or a CrN composite material layer, and the single shielding layer or each of the plurality of shielding layers is an amorphous carbon layer having a thickness of about 10 to 500 nm.

7. A shielding film, comprising:
a base structure;
a medium structure formed on the base structure; and
a shielding structure formed on the medium structure;
wherein the entire shielding structure is of a non-volatile substance, so that the porosity of the shielding structure is zero or close to zero.

8. The shielding film of claim 7, wherein the medium structure is formed on the base structure by vacuum sputtering, evaporation, physical vapor deposition or chemical vapor deposition, and the shielding structure is formed on the medium structure by vacuum sputtering, evaporation, physical vapor deposition or chemical vapor deposition, wherein the base structure is an Al base, a Cu base or a composite base having an Al layer and a PET layer, the medium structure with a thickness of about 10 to 200 nm is a Ti material layer, a Cr material layer, a Ta material layer, a TiN composite material layer, a TaN composite material layer or a CrN composite material layer, and the shielding structure is an amorphous carbon layer having a thickness of about 10 to 500 nm, and wherein the shielding structure is a high density structure without voids or with few voids, so that at least one of an electric conductivity, a thermal conductivity, an EMI shielding performance and a flexibility of the shielding film is increased.

9. The shielding film of claim 7, wherein the medium structure is a single medium layer or a plurality of medium layers stacked on top of one another, and the shielding structure is a single shielding layer or a plurality of shielding layers stacked on top of one another, wherein the single medium layer or each of the plurality of medium layers has a thickness of about 10 to 200 nm and is a Ti material layer, a Cr material layer, a Ta material layer, a TiN composite material layer, a TaN composite material layer or a CrN composite material layer, and the single shielding layer or each of the plurality of shielding layers is an amorphous carbon layer having a thickness of about 10 to 500 nm, and wherein the shielding structure is a high density structure without voids or with few voids, so that at least one of an electric conductivity, a thermal conductivity, an EMI shielding performance and a flexibility of the shielding film is increased.

10. The shielding film of claim 7, further comprising a first intermetallic compound layer connected between the base structure and the medium structure by heat treatment, and a second intermetallic compound layer connected between the medium structure and the shielding structure by heat treatment, wherein the medium structure is a single medium layer or a plurality of medium layers stacked on top of one another, and the shielding structure is a single shielding layer or a plurality of shielding layers stacked on top of one another, wherein the single medium layer or each of the plurality of medium layers has a thickness of about 10 to 200 nm and is a Ti material layer, a Cr material layer, a Ta material layer, a TiN composite material layer, a TaN composite material layer or a CrN composite material layer, and the single shielding layer or each of the plurality of shielding layers is an amorphous carbon layer having a thickness of about 10 to 500 nm, and wherein the shielding structure is a high density structure without voids or with few voids, so that at least one of an electric conductivity, a thermal conductivity, an EMI shielding performance and a flexibility of the shielding film is increased.
